(19) United States
(12) Patent Application Publication
(10) Pub. No.: US 2025/0261321 A1
(43) Pub. Date: Aug. 14, 2025

(54) DISPLAY DEVICE

(71) Applicant: LG ELECTRONICS INC., Seoul (KR)

(72) Inventor: Yongseong KIM, Seoul (KR)

(73) Assignee: LG ELECTRONICS INC., Seoul (KR)

(21) Appl. No.: 19/116,646

(22) PCT Filed: Sep. 30, 2022
(86) PCT No.: PCT/KR2022/014822

§ 371 Date: Mar. 28, 2025

(51) Int. Cl. H05K 5/02

(52) U.S. Cl. CPC H05K 5/0247

(57) ABSTRACT

Disclosed is a display device. The display device includes: a display panel; a composite material plate located at the rear of the display panel; and a side frame located between the display panel and the composite material plate, fixed to the composite material plate, and to which the display panel is coupled, wherein the composite material plate may include: a front skin forming the front thereof; a rear skin forming the rear thereof and facing the front skin; a core that is located between the front skin and the rear skin and includes fibers; a receiving portion in which the front skin and the core is compressed to form a step difference that lowers the front skin; and a first cable hole located adjacent to the receiving portion and penetrating the front skin and the rear skin.

### TECHNICAL FIELD

The present disclosure relates to a display device.

### BACKGROUND ART

As the information society develops, the demand for display devices is also increasing in various forms. In response to this, various display devices such as Liquid Crystal Display Device (LCD), Plasma Display Panel (PDP), Electroluminescent Display (ELD), Vacuum Fluorescent Display (VFD), and Organic Light Emitting Diode (OLED) have been researched and used in recent years.

Among them, a display device using an organic light emitting diode (OLED) has superior luminance and viewing angle compared to a liquid crystal display device, and may be implemented in an ultra-thin shape as it does not require a backlight unit.

Recently, much research has been conducted on structures for securing the rigidity of a large-screen ultra-thin display device and for heat dissipation according to high image quality.

### DISCLOSURE

### Technical Problem

An object of the present disclosure is to solve the above-described problems and other problems.

Another object of the present disclosure may be to secure a structural rigidity of a large-screen ultra-thin display device.

Another object of the present disclosure may be to prevent thermal deformation of the display device and secure high-temperature reliability.

Another object of the present disclosure may be to provide a display device that can prevent damage to a wired cable.

### Technical Solution

According to an aspect of the present disclosure, there is provided a display device including: a display panel; a material complexed plate located at a rear of the display panel; and a side frame which is located between the display panel and the material complexed plate, fixed to the material complexed plate, and to which the display panel is coupled, in which the material complexed plate includes: a front skin forming a front surface; a rear skin which forms a rear surface, and faces the front skin; a core which is located between the front skin and the rear skin, and contains fibers; a receiving portion in which the front skin and the core is compressed to form a step difference that lowers the front skin; and a first cable hole which is located adjacent to the receiving portion, and penetrates the front skin and the rear skin.

### Advantageous Effects

The effects of the display device according to the present disclosure will be described as follows.

According to at least one of the embodiments of the present disclosure, it is possible to secure a structural rigidity of a large-screen ultra-thin display device.

According to at least one of the embodiments of the present disclosure, it is possible to prevent thermal deformation of the display device and secure high-temperature reliability.

According to at least one of the embodiments of the present disclosure, there is provided a display device that can prevent damage to a wired cable.

Further scope of applicability of the present disclosure will become apparent from the following detailed description. However, it should be understood that the detailed description and specific embodiments such as preferred embodiments of the present disclosure are given by way of illustration only, since various changes and modifications within the spirit and scope of the present disclosure may be clearly understood by those skilled in the art.

### Description of Drawings

FIGS. 1 to 29 are diagrams illustrating examples of a display device according to embodiments of the present disclosure.

### Mode for Invention

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

Although an embodiment is described with reference to a specific drawing, if necessary, reference numerals not appearing in the specific drawing may be mentioned, and reference numerals not appearing in the specific drawing shall be used when the reference numerals appear in the other figures.

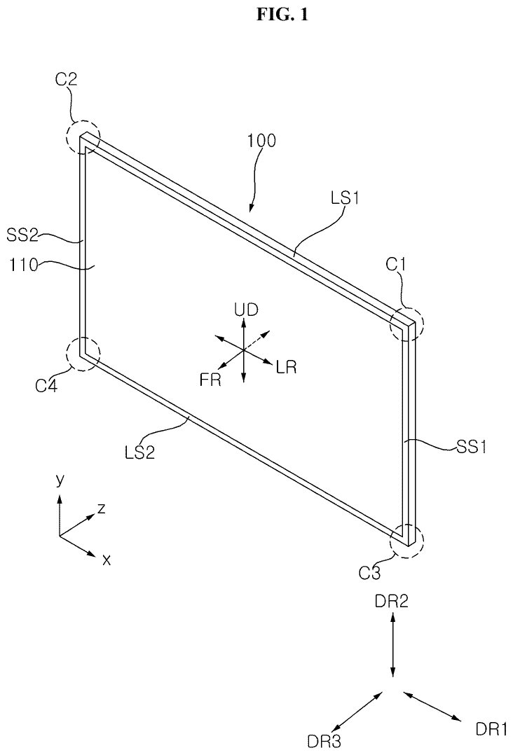

Referring to FIG. 1, a display device 100 may include a display panel 110. The display panel 110 may display an image.

The display device 100 may include a first long side LS1, a second long side LS2 opposite to the first long side LS1, a first short side SS1 adjacent to the first and second long sides LS1 and LS2, and a second short side SS2 opposite to the first short side SS1.

Meanwhile, for convenience of description, it is illustrated that the lengths of the first and second long sides LS1 and LS2 are longer than the lengths of the first and second short sides SS1 and SS2, but it may also be possible that the lengths of the first and second long sides LS1 and LS2 are approximately equal to the lengths of the first and second short sides SS1 and SS2.

The direction parallel to the long sides LS1 and LS2 of the display device 100 may be referred to as a left-right direction or a first direction DR1. The direction parallel to the short sides SS1 and SS2 of the display device 100 may be referred to as a vertical direction or a second direction DR2. The direction perpendicular to the long sides LS1 and LS2 and the short sides SSI and SS2 of the display device 100 may be referred to as a forward/rearward direction or a third direction DR3.

The direction in which the display panel 110 displays images may be referred to as a forward direction (F, z), and the opposite direction may be referred to as a rearward direction R. Here, the direction in which the display panel 110 displays an image may be referred to as a forward direction, and the opposite direction may be referred to as the rearward direction.

Hereinafter, a display panel using an organic light emitting diode (OLED) will be described as an example for the display panel 110, but the display panel 110 applicable to the present disclosure is not limited thereto.

The display panel 110 may form the front surface of the display device 100 and may display an image in a forward direction. The display panel 110 may output an image by dividing the image into a plurality of pixels and adjusting the color, brightness, and saturation for each pixel. The display panel 110 may be divided into an active area where an image is displayed and a de-active area where an image is not displayed. The display panel 110 may generate light corresponding to the color of red, green, or blue according to a control signal.

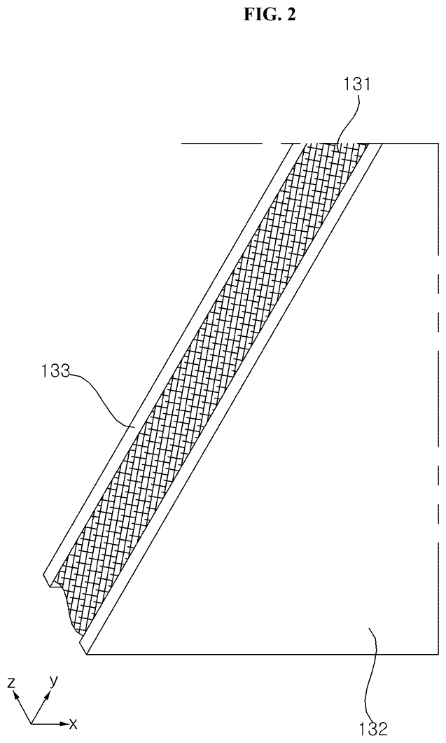

Referring to FIG. 2, a material complexed panel 130 may include a core 131, a front skin 132, and a rear skin 133. The core 131, the front skin 132, and the rear skin 133 may be coupled with each other. The material complexed panel 130 may be referred to as a fiber complexed panel 130, a fiber complexed plate 130, a material complexed plate 130, or a middle frame 130.

The front skin 132 may form the front surface of the material complexed panel 130. The rear skin 133 may form the rear surface of the material complexed panel 130. The front skin 132 and the rear skin 133 may include a metal material.

For example, the front skin 132 and the rear skin 133 may be galvanized iron. For another example, the front skin 132 and the rear skin 133 may include aluminum Al.

For example, the thickness of the front skin 132 and the rear skin 133 may be 0.2 to 0.5 millimeters. For another example, the front skin 132 and the rear skin 133 formed of galvanized iron may be 0.27 millimeters. For another example, the front skin 132 and the rear skin 133 including aluminum may be 0.5 millimeters.

The front skin 132 and the rear skin 133 may be opposite to each other with respect to the core 131 described below. The core 131 may be located between the front skin 132 and the rear skin 133. The core 131 may include a fiber. The core 131 may be formed of a material complexed. The core 131 may include a main fiber and a binder fiber. The binder fiber may be mixed between the main fibers.

The front skin 132 and/or the rear skin 133 may be coupled to the core 131 by a hot melt method. A hot melt sheet may be located between the front skin 132 and the core 131, and a hot melt sheet may be located between the rear skin 133 and the core 131. The hot melt sheet may be a film. For example, the hot melt sheet may be a film of EVA, acrylic, polyurethane, etc. having a thickness of 50 micrometers or more. After the core 131 is located between the front skin 132 and the rear skin 133 by the hot melt sheet, it may be roll laminated at 190 degrees Celsius for at least 1 minute.

Accordingly, the bending rigidity and/or torsional rigidity of the display device may be improved.

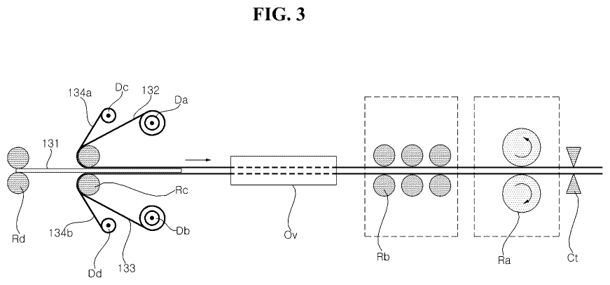

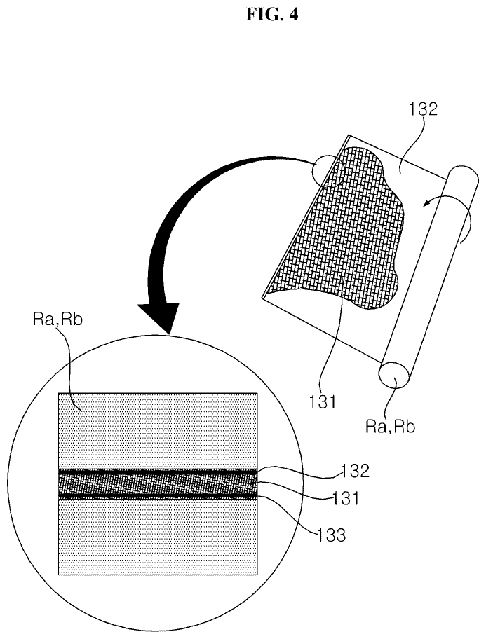

Referring to FIGS. 3 and 4, the material complexed panel 130 may be manufactured through a process of pressing the front skin 132 and the rear skin 133 to the core 131 by using a plurality of rollers, and such a process may be called a roll-to-roll process.

Referring to FIG. 3, according to the rotation of the pinch roller Ra performing the function of a driving motor, the front skin 132 may be released from a front drum Da, the rear skin 133 may be released from a rear drum Db, and the core 131 may be moved via a feeding roller Rd. Then, a first adhesive 134a for coupling the front skin 132 to the core 131 may be released from the first drum Dc. In addition, a second adhesive 134b for coupling the rear skin 133 to the core 131 may be released from the second drum Db. In this case, the front skin 132, the first adhesive 134a, the core 131, the second adhesive 134b, and the rear skin 133 may be laminated in this order, and may be guided in the direction toward the oven Ov by a guide roller Rc. The adhesive 134a, 134b may be a hot melt sheet 134a, 134b.

The first and second adhesives 134a, 134b may be melt in the oven Ov, and each of the front skin 132 and the rear skin 133 may be coupled to the core 131. For example, the melting points of the first and second adhesives 134a, 134b may be about 150° C., and the ambient temperature of the oven Ov may be about 200° C. For example, the peel-off force of the first and second adhesives 134a, 134b may be about 10 kgf or more.

The front skin 132, core 131 and rear skin 133 that have passed through the oven Ov may be guided to the pressing roller Rb and pressed by the pressing roller Rb according to the rotation of the pinch roller Ra. Accordingly, the coupling force between the front skin 132, the core 131 and the rear skin 133 may be further increased. The front skin 132, core 131 and rear skin 133 that have been mutually coupled may be cut by a cutter Ct after passing through the pinch roller Ra to be manufactured into a material complexed panel 130 of a certain size.

Referring to FIG. 4, the pressing roller Rb or the pinch roller Ra may be in contact with the outer surface of each of the front skin 132 and the rear skin 133. When the pressing roller Rb or pinch roller Ra rotates, the material complexed panel 130 may move in the longitudinal direction (i.e., left-right direction LR) of the core 131. At this time, the front skin 132 and the rear skin 133 may be sequentially coupled from one end of the core 131 to the other end in the longitudinal direction of the core 131.

In addition, the front skin 132 and the rear skin 133 of the material complexed panel 130 may be formed flat. That is, since the rear surface of the rear skin 133 forming the rear surface of the display device 100 is formed flat, it may be easy to perform additional work such as painting or attaching a sheet to the rear surface of the rear skin 133 for aesthetic purposes.

Meanwhile, in addition to forming the front skin 132 and the rear skin 133 flatly through the roll-to-roll process described above with reference to FIGS. 3 and 4, it is also possible to couple the core 131, the front skin 132, and the rear skin 133 through a process of sequentially laminating the front skin 132, the core 131, and the rear skin 133 and then coupling them.

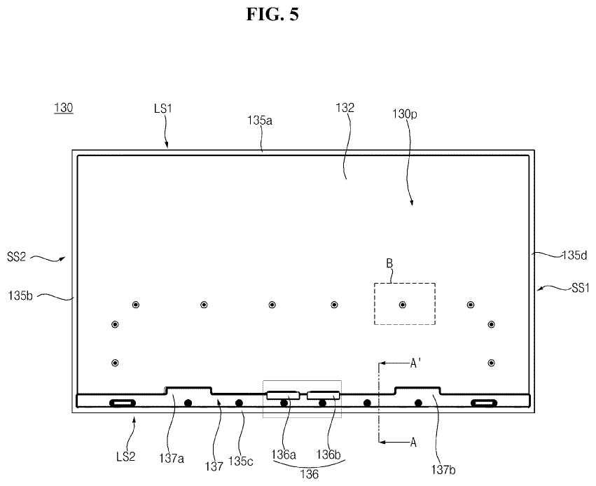

Referring to FIG. 5, the material complexed panel 130 may include a flat portion 130P, a receiving portion 137, and an outer part 135. The outer part 135 may be formed around the flat portion 130P. A first outer part 135a may be formed along the upper side of the flat portion 130P, a second outer part 135b may be formed along the left side of the flat portion 130P, a third outer part 135c may be formed along the lower side of the flat portion 130P, and a fourth outer part 135d may be formed along the right side of the flat portion 130P. The outer part 135 may be formed while the flat portion 130P is pressed. The outer part 135 may form a step while being lowered from the flat portion 130P. The thickness of the flat portion 130P may be greater than the thickness of the outer part 135.

A cable hole 136 may be formed by penetrating the front skin 132 (see FIG. 2) and the rear skin 133 (see FIG. 2) of the receiving portion 137. The cable hole 136 may be formed in the receiving portion 137 adjacent to the lower side of the flat portion 130P. There may be a plurality of cable holes 136. A first cable hole 136a may be located adjacent to a second cable hole 136b.

The receiving portion 137 may be formed between the flat portion 130P and the third outer part 135c while being adjacent to the lower side of the flat portion 130P. There may be a plurality of receiving portions 137. A first receiving portion 137a may be located between the first cable hole 136a and the second short side SS2. A second receiving portion 137b may be located between the second cable hole 136b and the first short side SS1. The receiving portion 137 may be formed while the flat portion 130P is pressed. The receiving portion 137 may form a step while being lowered from the flat portion 130P and/or the outer part 135c.

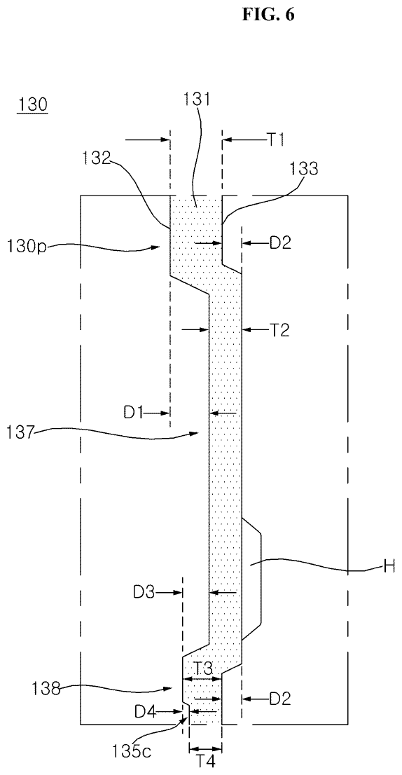

Referring to FIG. 6, the receiving portion 137 may be formed while the flat portion 130P is pressed. The front skin 132 of the receiving portion 137 may form a step D1 that is lowered from the front skin 132 of the flat portion 130P. The rear skin 133 of the receiving portion 137 may form a step D2 that rises from the rear skin 133 of the flat portion 130P. At this time, the height of the step D1 that is lowered from the front skin 132 of the flat portion 130P to the front skin 132 of the receiving portion 137 may be greater than the height of the step D2 that rises from the rear skin 133 of the flat portion 130P to the rear skin 133 of the receiving portion 137. The thickness T1 of the flat portion 130P may be greater than the thickness T2 of the receiving portion 137.

When pressed from the front skin 132 of the flat portion 130P toward the rear skin 133, the core 131 of the material complexed panel 130 may absorb external force. The magnitude of the external force applied to the front skin 132 of the flat portion 130P may be greater than the magnitude of the external force applied to the rear skin 133 of the flat portion 130P. The core 131 of the material complexed panel 130 may not only secure rigidity but also absorb impact.

The thickness T4 of the third outer part 135c may be greater than the thickness T2 of the receiving portion 137. A step D2 that is raised from the rear skin 133 of the third outer part 135c to the rear skin 133 of the receiving portion 137 may be formed. The height of the step D2 between the rear skin 133 of the third outer part 135c and the rear skin 133 of the receiving portion 137 may be the same as the height of the step D2 between the rear skin 133 of the receiving portion 137 and the rear skin 133 of the flat portion 130P.

A protruding pad 138 may be formed by protruding from the front skin 132 of the third outer part 135c. The front skin 132 of the protruding pad 138 may form a step D4 that is lowered to the front skin 132 of the third outer part 135c. The height of the step D4 formed by the third outer part 135c and the protruding pad 138 may be smaller than the height of the step D1, D2 formed by the flat portion 130P and the receiving portion 137. A step D3 may be formed that is lowered from the front skin 132 of the protruding pad 138 to the front skin 132 of the receiving portion 137. The thickness T3 of the protruding pad 138 may be larger than the thickness T4 of the third outer part 135c, smaller than the thickness T1 of the flat portion 130P, and smaller than the thickness T2 of the receiving portion 137.

The fastening groove H may protrude from the rear skin 133 of the receiving portion 137. The fastening groove H may be recessed from the front skin 132 of the receiving portion 137 and may protrude from the rear skin 133 of the receiving portion 137. The center of the fastening groove H may be penetrated.

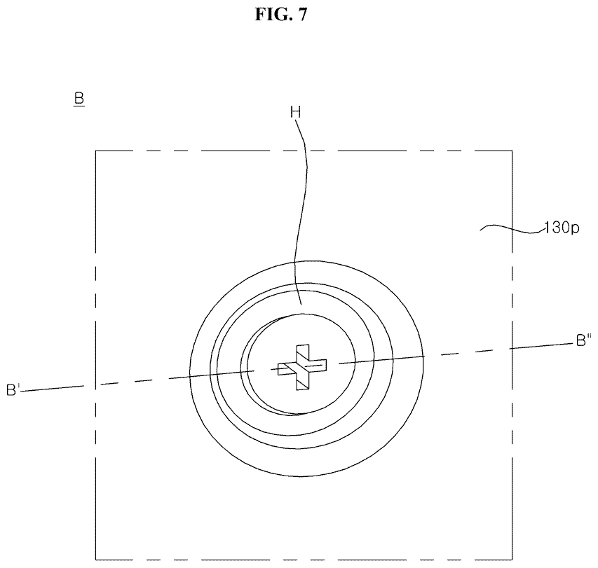

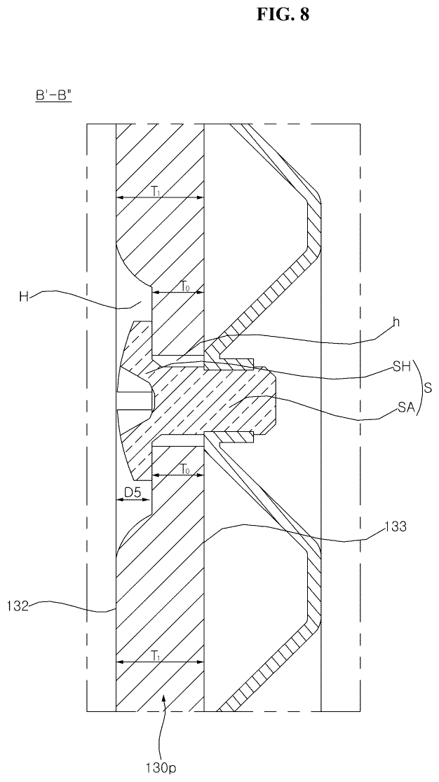

Referring to FIGS. 7 and 8, the fastening groove H may be formed in the flat portion 130P. The fastening groove H may be formed while the flat portion 130P is pressed. The front skin 132 of the fastening groove H may be recessed from the front skin 132 of the flat portion 130P. The rear skin 133 of the flat portion 130P and the rear skin 133 of the fastening groove H may form the same plane. The thickness T0 of the fastening groove H may be smaller than the thickness T1 of the flat portion 130P.

A fastening hole h may be formed in the center of the fastening groove H. The fastening hole h may be formed by punching the fastening groove H. The fastening hole h may be formed by penetrating the front skin 132 and the rear skin 133 of the fastening groove H. The length of the shaft SA of the fastening member S may be greater than the thickness TO of the fastening groove H. The shaft SA of the fastening member S may be inserted into the fastening groove H and may protrude outwardly from the rear skin 132 of the fastening groove H through the fastening hole h. The depth D5 of the fastening groove H may be greater than the thickness of the head SH. The head SH of the fastening member S may be concealed in the fastening groove H.

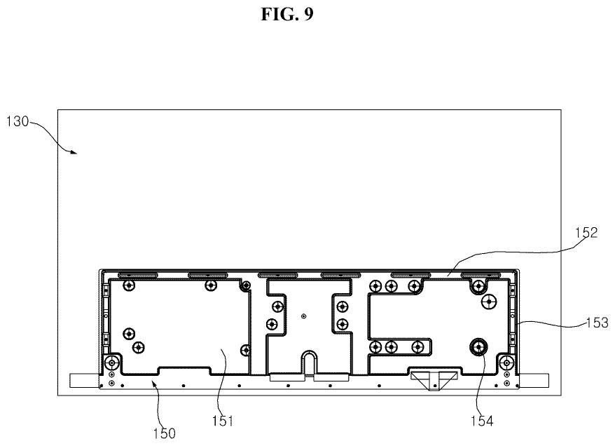

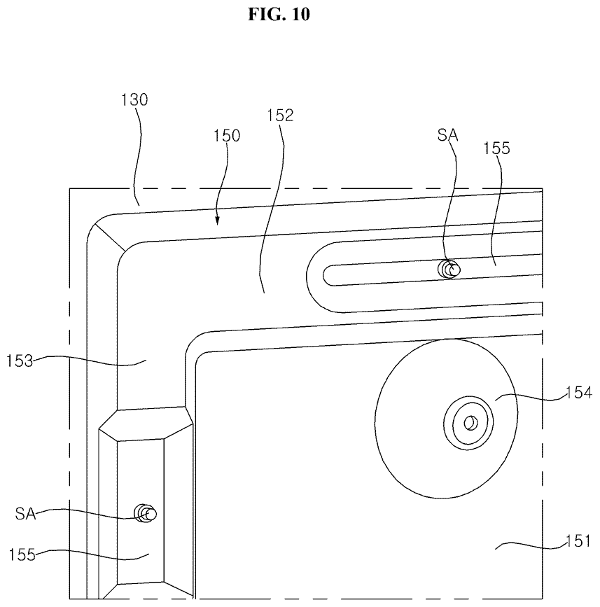

Referring to FIGS. 9 and 10 together with FIG. 8, the PCB plate 150 may be coupled to the rear of the material complexed panel 130. The PCB plate 150 may be fixed to the rear of the material complexed panel 130 by the fastening member S.

The PCB plate 150 may be formed by pressing the plate 151 including metal. The PCB plate 150 may have a horizontal portion 152, a vertical portion 153, a dome portion 154, and a recessed portion 155. The horizontal portion 152 may be formed by protruding from the front to the rear of the PCB plate 151 and extending long in the left-right direction of the PCB plate 151. The vertical portion 153 may be formed by protruding from the front to the rear of the PCB plate 151 and extending long in the up-down direction of the PCB plate 150. The dome portion 154 may protrude from the front to the rear of the PCB plate 150. The recessed portion 155 may recess in a forward direction from the rear of the vertical portion 153 and/or the horizontal portion 152.

The shaft SA of the fastening member S may penetrate the recessed portion 155 formed in the vertical portion 153 and/or the horizontal portion 152 to couple the material complexed panel 130 and the PCB plate 150. The depth of the recessed portion 155 may be greater than the protrusion length of the shaft SA of the fastening member S that protrudes in a rearward direction by penetrating the material complexed panel 130.

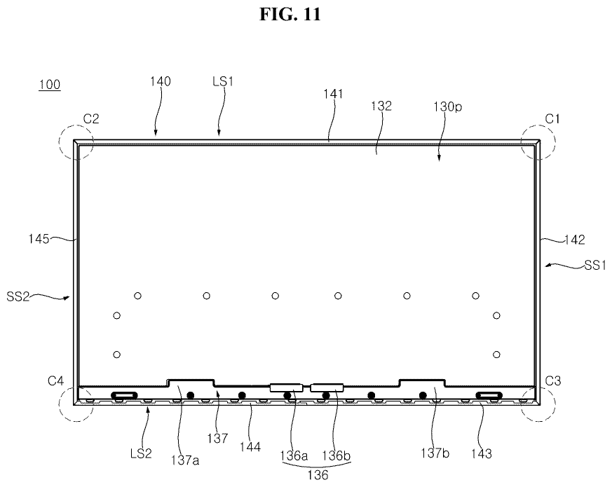

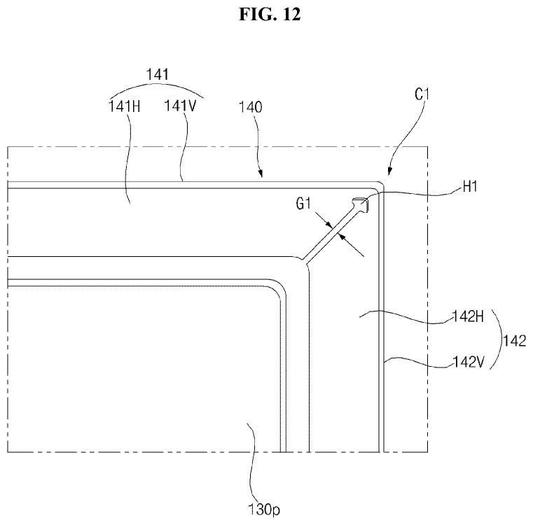

Referring to FIGS. 11 and 12, the side frame 140 may be coupled to the outer part 135 (see FIG. 5) adjacent to the flat portion 130P. The side frame 140 may have a first part 141, a second part 142, a third part 143, a fourth part 144, and a fifth part 145. The second part 142 may be bent from the first part 141 at a first corner C1.

The first part 141 may have a horizontal portion 141H and a vertical portion 141V. The horizontal portion 141H of the first part 141 may be fixed on a first outer part 135a (see FIG. 5). The second part 142 may have a horizontal portion 142H and a vertical portion 142V. The horizontal portion 142H of the second part 142 may be fixed on a fourth outer part 135d (see FIG. 5).

A gap G1 may be formed between the horizontal portion 141H of the first part 141 and the horizontal portion 142H of the second part 142. The vertical portion 141V of the first part 141 and the vertical portion 142V of the second part 142 may be connected while being bent. A hole H1 connected to the gap G1 may be formed between the horizontal portions 141H, 142H while being adjacent to the vertical portions 141V, 142V. The size of the hole H1 or the diameter of the hole H1 may be larger than the width of the gap G1. The description of the first corner C1 of the side frame 140 may be identically applied to the second corner C2 of the side frame 140.

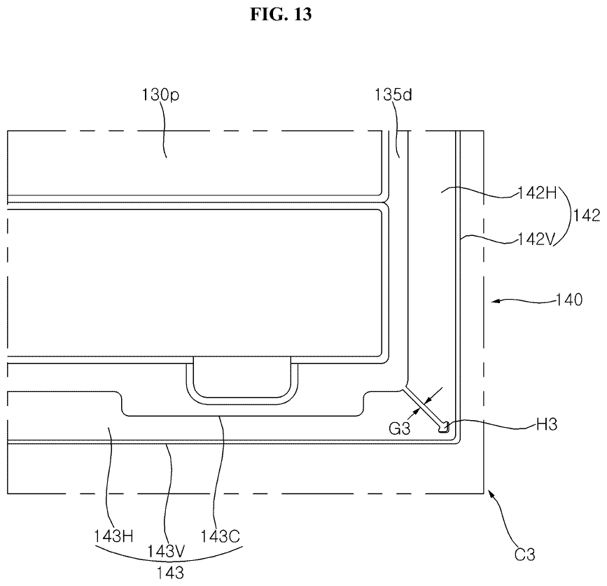

Referring to FIGS. 11 and 13, the side frame 140 may be coupled to the outer part 135 (see FIG. 5) while being adjacent to the flat portion 130P. The side frame 140 may have a first part 141, a second part 142, a third part 143, a fourth part 144, and a fifth part 145. The second part 142 may be bent from the third part 143 at a third corner C3.

The third part 143 may have a horizontal portion 143H and a vertical portion 143V. The horizontal portion 143H of the third part 143 may be fixed on the third outer part 135c (see FIG. 5). The second part 142 may have a horizontal portion 142H and a vertical portion 142V. The horizontal portion 142H of the second part 142 may be fixed on the fourth outer part 135d (see FIG. 5).

A gap G3 may be formed between the horizontal portion 143H of the third part 143 and the horizontal portion 142H of the second part 142. The vertical portion 143V of the third part 143 and the vertical portion 142V of the second part 142 may be connected while being bent. A hole H3 may be formed between the horizontal portions 143H, 142H while being adjacent to the vertical portions 143V, 142V and being connected to the gap G3. The size of the hole H3 or the diameter of the hole H3 may be larger than the width of the gap G3. The description of the first corner C3 of the side frame 140 may be identically applied to the fourth corner C4 of the side frame 140.

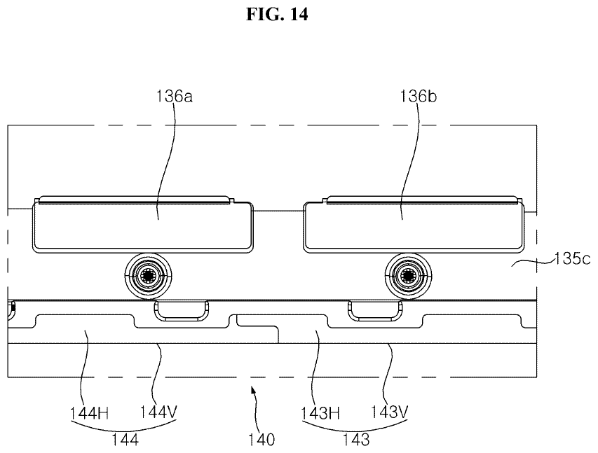

Referring to FIGS. 11 and 14, the third part 143 and the fourth part 144 of the side frame 140 may be located or fixed on the third outer part 135c. The distal end of the third part 143 of the side frame 140 may be coupled with the distal end of the fourth part 144 of the side frame 140.

The horizontal portion 144H of the fourth part 144 may be in contact with the horizontal portion 143H and the vertical portion 143V of the third part 143. The vertical portion 144V of the fourth part 144 may be in contact with the vertical portion 143V of the third part 143. The vertical portion 143V of the third part 143 may be in contact with the horizontal portion 144H and the vertical portion 144V of the fourth part 144. The distal end of the third part 143 may be fixed to the distal end of the fourth part 144. For example, the distal end of the third part 143 and the distal end of the fourth part 144 may be fixed by welding.

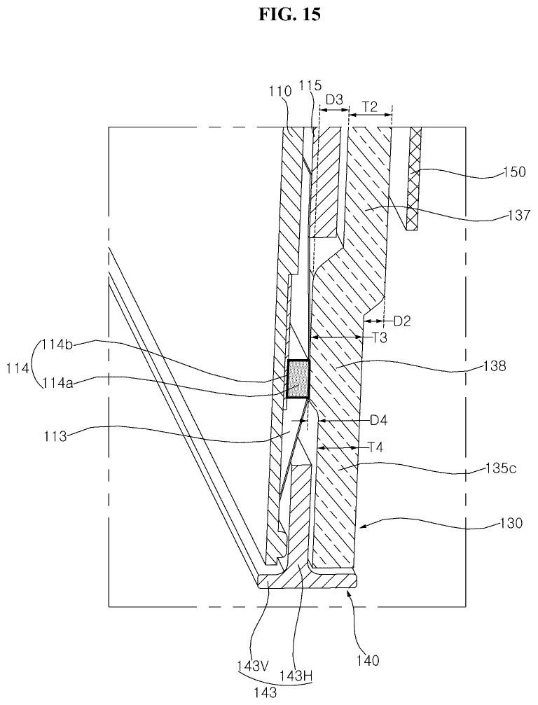

Referring to FIG. 15, the display panel 110 may be coupled or fixed on the side frame 140. The horizontal portion 143H of the side frame 140 may support the rear surface of the display panel 110, and the vertical portion 143V may cover the side surface of the display panel 110. For example, the vertical portion 143V of the third part 143 of the side frame 140 may cover the side surface of the lower side of the display panel 110.

The vertical portion 143V may cover the side surface of the material complexed panel 130. For example, the vertical portion 143V of the third part 143 of the side frame 140 may cover the side surface of the third outer part 135c of the material complexed panel 130.

The flexible cable 113 may extend from the lower side of the display panel 110 to between the display panel 110 and the horizontal portion 143H of the side frame 140. The flexible cable 113 may extend to between the rear surface of the display panel 110 and the material complexed panel 130. For example, the flexible cable 113 may be a COF 113.

The source signal substrate 115 may be electrically connected to the flexible cable 113. The source signal substrate 115 may be fixed to one surface of the flexible cable 113. For example, the source signal substrate 115 may be an S-PCB 115. The source signal substrate 115 may be located in the receiving portion 137 of the material complexed panel 130.

The flexible cable 113 may be located between the protruding pad 138 of the material complexed panel 130 and the display panel 110. The flexible cable 113 may be in contact with the protruding pad 138. Heat generated from the source signal substrate 115 and/or the flexible cable 113 may be dissipated through the protruding pad 138.

A heat dissipation pad 114 may be located between the flexible cable 113 in contact with the protruding pad 138 and the rear surface of the display panel 110. The heat dissipation pad 114 may have an elastic material 114a and a conductive film 114b. The core 114a of the heat dissipation pad 114 may be formed of an elastic material, and the conductive film 114b may cover the core 114a of the heat dissipation pad 114. Accordingly, the flexible cable 113 may be maintained in contact with the protruding pad 138.

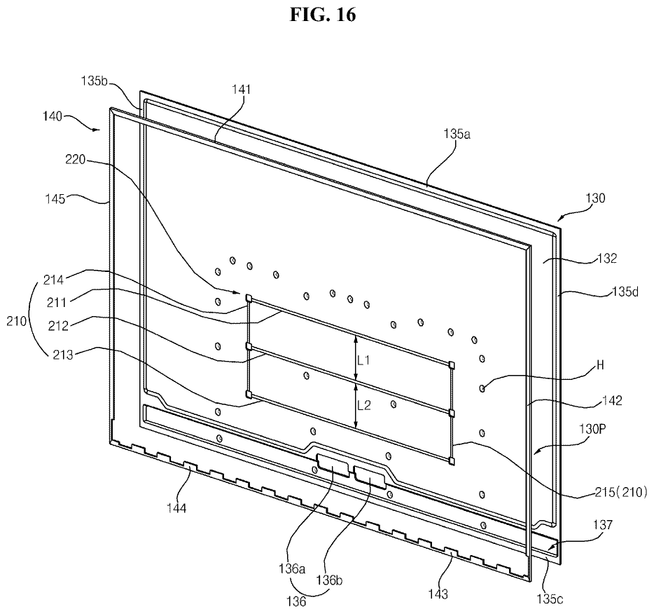

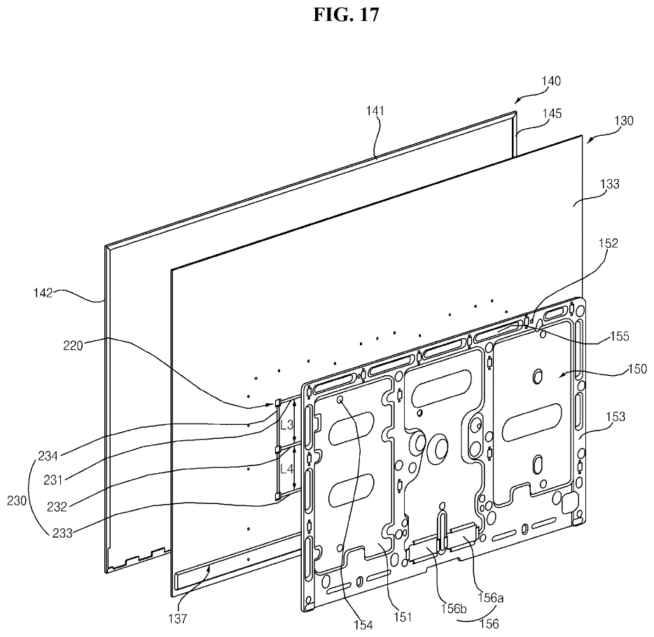

Referring to FIGS. 16 and 17, the inner frame 210, 230 may be formed on the front surface and/or rear surface of the material complexed panel 130. The inner frame 210, 230 may be referred to as a pressed frame 210, 230 or a rigid line 210, 230. The inner frame 210, 230 may be formed as the front skin 132 and/or the rear skin 133 of the material complexed panel 130 is depressed and the core 131 (see FIG. 2) is compressed.

The inner frame 210, 230 may include a front inner line 210, a rear inner line 230, and a node hole 220. The front inner line 210 may be formed by depressing the front skin 132 of the material complexed panel 130. The rear inner line 230 may be formed by depressing the rear skin 133 of the material complexed panel 130.

The front inner line 210 may include a first front horizontal line 211, a second front horizontal line 212, a third front horizontal line 213, a first front vertical line 214, and a second front vertical line 215. The first front horizontal line 214 may form an upper side of the front inner line 210. The third front horizontal line 213 may form a lower side of the front inner line 210. The second front horizontal line 212 may be located between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213. For example, the first distance L1 between the first front horizontal line 211 and the second front horizontal line 212 may be smaller than the second distance L2 between the second front horizontal line 212 and the third front horizontal line 213.

The node hole 220 may be formed at a point where the front horizontal line 211, 212, 213 and the front vertical line 214, 215 meet. The node hole 220 may be formed by penetrating the front skin 132, the core 131, and the rear skin 133 of the material complexed panel 130.

The rear inner line 230 may include a first rear horizontal line 231, a second rear horizontal line 232, a third rear horizontal line 233, a first rear vertical line 234, and a second rear vertical line 235 (not shown). The first rear horizontal line 234 may form an upper side of the rear inner line 230. The third rear horizontal line 233 may form a lower side of the rear inner line 230. The second rear horizontal line 232 may be located between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 (not shown) may connect the other end of the first rear horizontal line 231, the other end of the second rear horizontal line 232, and the other end of the third rear horizontal line 233. For example, the third distance L3 between the first rear horizontal line 231 and the second rear horizontal line 232 may be smaller than the fourth distance L4 between the second rear horizontal line 232 and the third rear horizontal line 233.

The node hole 220 may be formed at a point where the rear horizontal line 231, 232, 233 and the rear vertical line 234, 235 meet. The node hole 220 may be formed by penetrating the front skin 132, the core 131, and the rear skin 133 of the material complexed panel 130.

The length of the rear inner line 230 may be smaller than the length of the PCB plate 150. The width of the rear inner line 230 may be smaller than the width of the PCB plate 150. The PCB plate 150 may cover the rear inner line 230. The PCB plate 150 may include a cable hole 156. The cable hole 156 of the PCB plate 150 may correspond to the cable hole 136 of the material complexed panel 130.

Accordingly, the bending rigidity and/or torsional rigidity of the material complexed panel 130 may be improved.

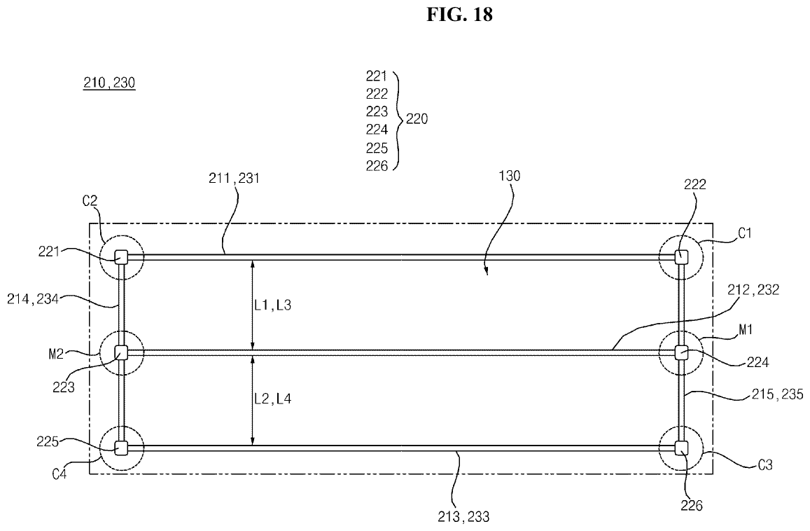

Referring to FIG. 18, there may be a plurality of node holes 220. The plurality of node holes 220 may include a first node hole 221, a second node hole 222, a third node hole 223, a fourth node hole 224, a fifth node hole 225, and a sixth node hole 226.

The first node hole 221 may be located at a corner C2 formed by the first horizontal line 211, 231 and the first vertical line 214, 234. The first node hole 221 may be formed by penetrating the material complexed panel 130 at the corner C2 of the first horizontal line 211, 231 and the first vertical line 214, 234.

The second node hole 222 may be located at a corner Cl formed by the first horizontal line 211, 231 and the second vertical line 212, 232. The second node hole 222 may be formed by penetrating the material complexed panel 130 at the corner C1 of the first horizontal line 211, 231 and the second vertical line 212, 232.

The third node hole 223 may be located at a node M2 formed by the second horizontal line 212, 232 and the first vertical line 214, 234. The third node hole 223 may be formed by penetrating the material complexed panel 130 at the node M2 of the second horizontal line 212, 232 and the first vertical line 214, 234.

The fourth node hole 224 may be located at a node M1 formed by the second horizontal line 212, 232 and the second vertical line 212, 232. The fourth node hole 224 may be formed by penetrating the material complexed panel 130 at the node M1 of the second horizontal line 212, 232 and the second vertical line 212, 232.

The fifth node hole 225 may be located at a corner C4 formed by the third horizontal line 213, 233 and the first vertical line 214, 234. The fifth node hole 225 may be formed by penetrating the material complexed panel 130 at the corner C4 of the third horizontal line 213, 233 and the first vertical line 214, 234.

The sixth node hole 226 may be located at a corner C3 formed by the third horizontal line 213, 233 and the second vertical line 212, 232. The sixth node hole 226 may be formed by penetrating the material complexed panel 130 at the corner C3 of the third horizontal line 213, 233 and the second vertical line 212, 232.

Accordingly, the bending rigidity and/or torsional rigidity of the material complexed panel 130 may be improved, as well as the flatness of the display panel 110 coupled to the material complexed panel 130 may be improved.

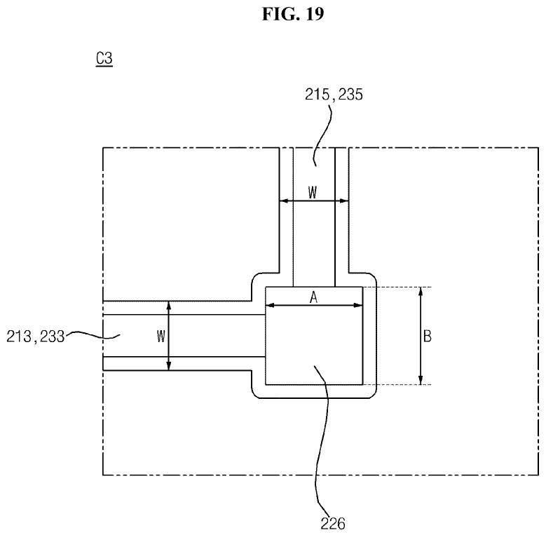

Referring to FIG. 19, the size of the sixth node hole 226 may be larger than the width of the third horizontal line 213, 233 and/or the second vertical line 215, 235. For example, if the sixth node hole 226 is square, the width A, B of the sixth node hole 226 may be larger than the width W of the third horizontal line 213, 233 and/or the second vertical line 215, 235. For another example, if the sixth node hole 226 is circular, the diameter of the sixth node hole 226 may be larger than the width of the third horizontal line 213, 233 and/or the second vertical line 215, 235. The description of the sixth node hole 226 may be applied to the first node hole 221, the second node hole 222, and/or the fifth node hole 225.

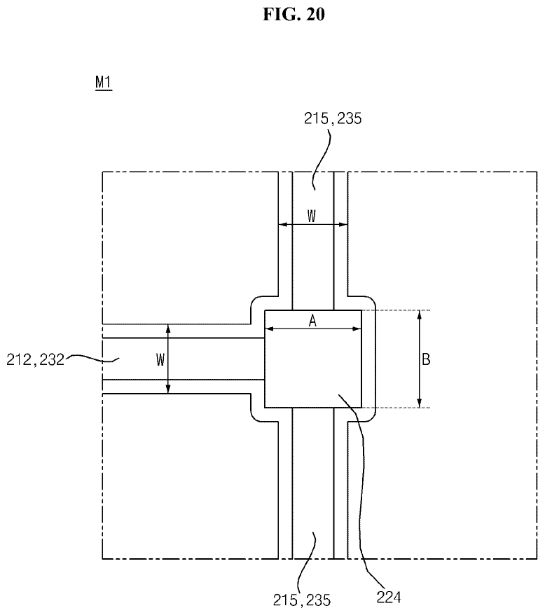

Referring to FIG. 20, the size of the fourth node hole 224 may be larger than the width of the second horizontal line 212, 232 and/or the second vertical line 215, 235. For example, if the fourth node hole 224 is square, the width A, B of the fourth node hole 224 may be larger than the width of the second horizontal line 212, 232 and/or the second vertical line 215, 235. For another example, if the fourth node hole 224 is circular, the diameter of the fourth node hole 224 may be larger than the width of the second horizontal line 212, 232 and/or the second vertical line 215, 235. The description of the fourth node hole 224 may also be applied to the third node hole 223.

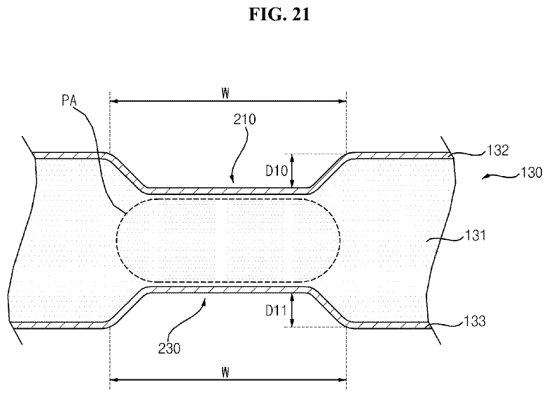

Referring to FIG. 21, the front inner line 210 may be formed in the material complexed panel 130 by allowing the front skin 132 to be recessed as the core 131 is compressed. The rear inner line 230 may be formed in the material complexed panel 130 by allowing the rear skin 133 to be recessed as the core 131 is compressed.

The front inner line 210 and the rear inner line 230 may be symmetrical with respect to the core 131. For example, the width W of the front inner line 210 may be substantially the same as the width W of the rear inner line 230. For another example, the depth D10 of the front inner line 210 may be substantially the same as the depth D11 of the rear inner line 230.

A pressed area PA in which the core 131 is compressed may be formed between the front inner line 210 and the rear inner line 230. The density of the core 131 in the pressed area PA may be greater than the density of the core 131 in a non-pressed area.

Accordingly, the bending rigidity and/or torsional rigidity of the material complexed panel 130 may be improved.

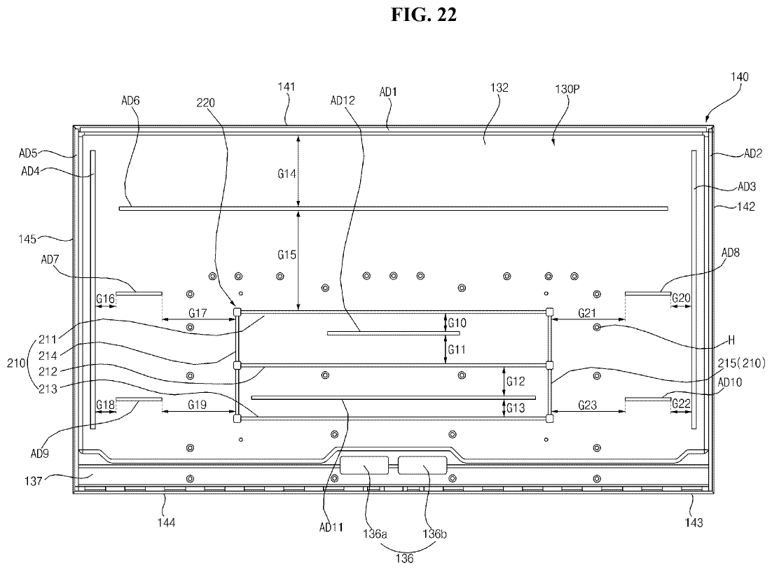

Referring to FIG. 22, the adhesive member AD may be arranged on the flat portion 130P of the material complexed panel 130. The adhesive member AD may be adhered to the front skin 132 of the material complexed panel 130. There may be a plurality of adhesive members AD.

A first adhesive member AD1 may be fixed to the first part 141 of the side frame 140. The first adhesive member AD1 may be extended along the longitudinal direction of the first part 141 of the side frame 140. A second adhesive member AD2 may be extended along the longitudinal direction of the second part 142 of the side frame 140 and may be fixed to the second part 142. A third adhesive member AD3 may be extended along the second part 142 of the side frame 140, may be parallel to the second part 142, and may be spaced apart from the first adhesive member AD1 so as to be fixed to the flat portion 130P.

A fifth adhesive member AD5 may be extended along the longitudinal direction of the fifth part 145 of the side frame 140 and may be fixed to the fifth part 145. A fourth adhesive member AD4 may be extended along the fifth part 145 of the side frame 140, parallel to the fifth part 145, and spaced apart from the fifth adhesive member AD5 so as to be fixed to the flat portion 130P.

A sixth adhesive member AD6 may be extended along the longitudinal direction of the first part 141 of the side frame 140, and spaced apart from the first adhesive member AD1 so as to be fixed to the flat portion 130P. A fourteenth distance G14 from the first part 141 of the side frame 140 to the sixth adhesive member AD6 may be smaller than a fifteenth distance G15 from the sixth adhesive member AD6 to the first front horizontal inner line 211.

A seventh adhesive member AD7 may extend along the longitudinal direction of the sixth adhesive member AD6, and be fixed to the flat portion 130P at between the first front vertical line 214 and the fourth adhesive member AD4. The seventh adhesive member AD7 may be located between the sixth adhesive member AD6 and a ninth adhesive member AD9. A sixteenth distance G16 from the fourth adhesive member AD4 to one distal end of the seventh adhesive member AD7 may be smaller than a seventeenth distance G17 from the first front vertical line 214 to the other distal end of the seventh adhesive member AD7.

The ninth adhesive member AD9 may extend along the longitudinal direction of the sixth adhesive member AD6, and be fixed to the flat portion 130P at between the first front vertical line 214 and the fourth adhesive member AD4. The ninth adhesive member AD9 may be located between the seventh adhesive member AD7 and the receiving portion 137. An eighteenth distance G18 from the fourth adhesive member AD4 to one distal end of the ninth adhesive member AD9 may be smaller than a nineteenth distance G19 from the first front vertical line 214 to the other distal end of the ninth adhesive member AD9.

An eighth adhesive member AD8 may extend along the longitudinal direction of the sixth adhesive member AD6 and may be fixed to the flat portion 130P at between the second front vertical line 215 and the third adhesive member AD3. The eighth adhesive member AD8 may be located between the sixth adhesive member AD6 and the receiving portion 137. A twentieth distance G20 from the third adhesive member AD3 to one distal end of the eighth adhesive member AD8 may be smaller than a twenty-first distance G21 from the second front vertical line 215 to the other distal end of the eighth adhesive member AD8.

A tenth adhesive member AD10 may extend along the longitudinal direction of the sixth adhesive member AD6 and may be fixed to the flat portion 130P at between the second front vertical line 215 and the third adhesive member AD3. The tenth adhesive member AD10 may be located between the eighth adhesive member AD8 and the receiving portion 137. A 22nd distance G22 from the third adhesive member AD3 to one distal end of the tenth adhesive member AD10 may be smaller than a 23rd distance G23 from the second front vertical line 215 to the other distal end of the tenth adhesive member AD10.

An eleventh adhesive member AD11 may be extended along the longitudinal direction of the second front horizontal line 212 and may be fixed to the flat portion 130P at between the second front horizontal line 212 and the third front horizontal line 213. A twelfth adhesive member AD12 may be extended along the longitudinal direction of the second front horizontal line 212, and may be located between the first front horizontal line 211 and the second front horizontal line 212. The length of the twelfth adhesive member AD12 may be smaller than the length of the eleventh adhesive member AD11.

A tenth distance G10 between the first front horizontal line 211 and the twelfth adhesive member AD12 may be smaller than an eleventh distance G11 between the twelfth adhesive member AD12 and the second front horizontal line 212. For example, the tenth distance G10 may be 40 millimeters or more. For example, the distance between one distal end of the twelfth adhesive member AD12 and the first vertical front line 214 may be 20 millimeters or more. For another example, the distance between the other distal end of the twelfth adhesive member AD12 and the second vertical front line 215 may be 20 millimeters or more.

A twelfth distance G12 between the second front horizontal line 212 and the eleventh adhesive member AD11 may be larger than a thirteenth distance G13 between the eleventh adhesive member AD11 and the third front horizontal line 213. For example, the thirteenth distance G13 may be 40 millimeters or more.

The display panel 110 may be coupled or fixed to the material complexed panel 130 by the adhesive member AD. Accordingly, the display panel 110 may be fixed flatly to the material complexed panel 130.

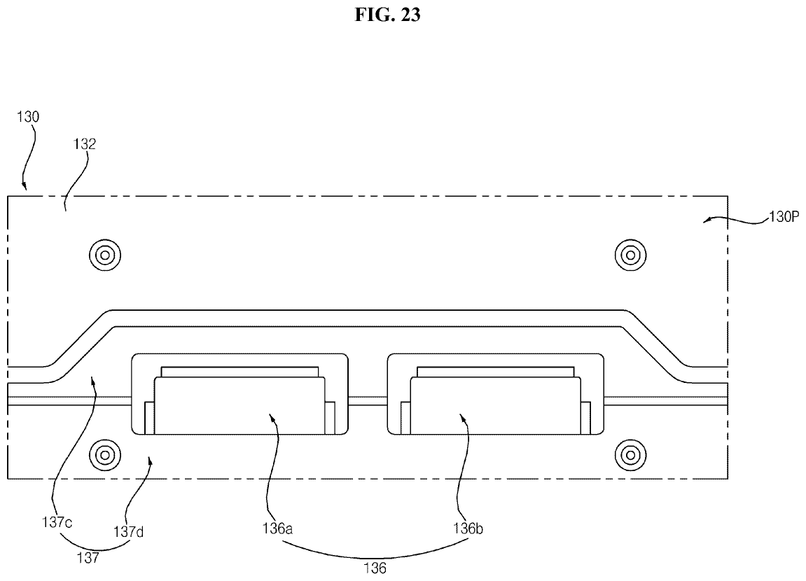

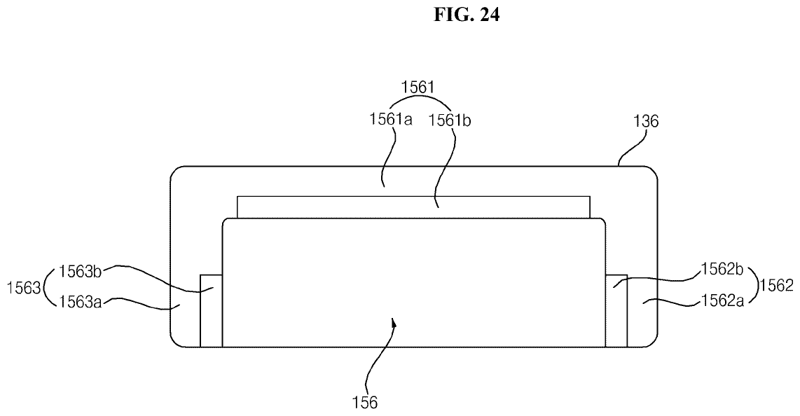

Referring to FIGS. 23 and 24 together with FIG. 17, the receiving portion 137 may include an inner receiving portion 137c and an outer receiving portion 137d. The inner receiving portion 137c may form a step lowered from the flat portion 130P and may be located between the outer receiving portion 137d and the flat portion 130P. The outer receiving portion 137d may form a step lowered from the inner receiving portion 137c. The cable hole 136 may be formed by penetrating the inner receiving portion 137c and/or the outer receiving portion 137d. The cable hole 136 may be formed by penetrating the boundary between the inner receiving portion 137c and the outer receiving portion 137d.

The PCB plate 150 may include a hole side part 1561, 1562, 1563. The hole side part 1561, 1562, 1563 may form a perimeter of the cable hole 156 of the PCB plate 150. The size of the cable hole 156 of the PCB plate 150 may be smaller than the size of the cable hole 136 of the material complexed panel 130.

The hole side part 1561, 1562, 1563 may include a first side part 1561, a second side part 1562, and a third side part 1563. The first side part 1561 may form the upper side of the cable hole 156 of the PCB plate 150. The second side part 1562 may form the right side of the cable hole 156 of the PCB plate 150. The third side part 1563 may form the left side of the cable hole 156 of the PCB plate 150.

The first side part 1561 may include a first rear part 1561a and a first front part 1561b. The first rear part 1561a may be connected to the plate 151 of the PCB plate 150. The first front part 1561b may be formed by folding or curling the first rear part 1561a. The first front part 1561b may face the front surface of the first rear part 1561a.

The second side part 1562 may include a second rear part 1562a and a second front part 1562b. The second rear part 1562a may be connected to the plate 151 of the PCB plate 150. The second front part 1562b may be formed by folding or curling the second rear part 1562a. The second front part 1562b may face the front surface of the second rear part 1562a.

The third side part 1563 may include a third rear part 1563a and a third front part 1563b. The third rear part 1563a may be connected to the plate 151 of the PCB plate 150. The third front part 1563b may be formed by folding or curling the third rear part 1563a. The third front part 1563b may face the front surface of the third rear part 1563a.

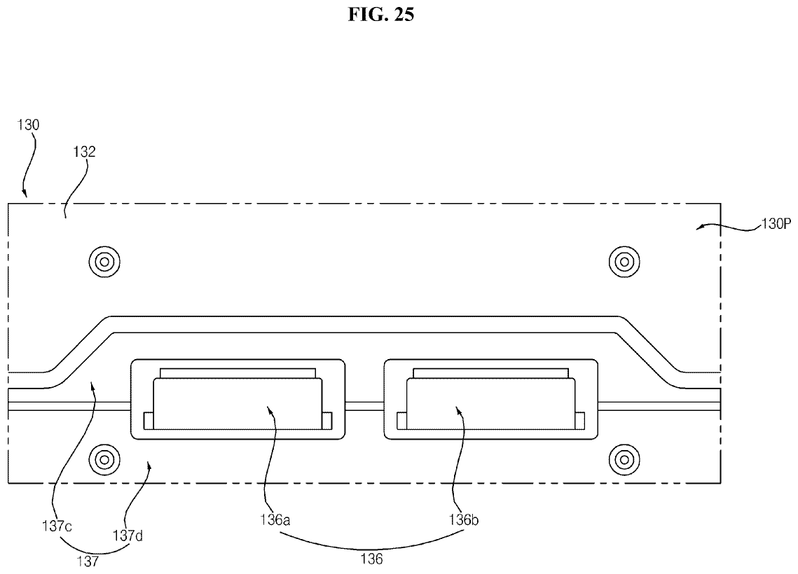

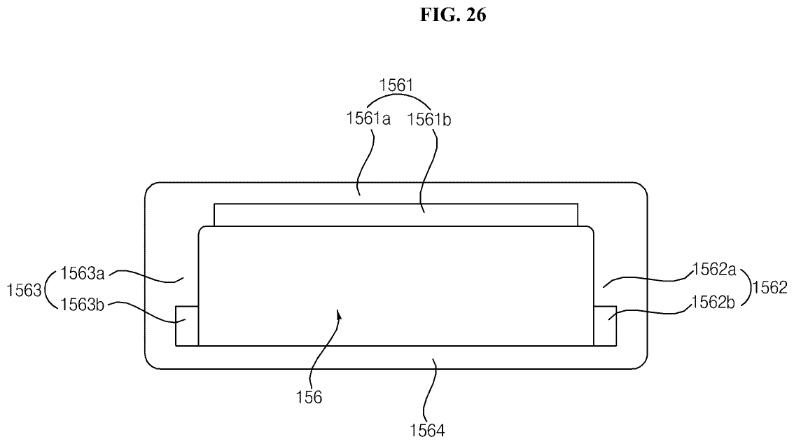

Referring to FIGS. 25 and 26, the PCB plate 150 may include a hole side part 1561, 1562, 1563, 1564. The hole side part 1561, 1562, 1563, 1564 may form a perimeter of the cable hole 156 of the PCB plate 150. The size of the cable hole 156 of the PCB plate 150 may be smaller than the size of the cable hole 136 of the material complexed panel 130.

The hole side part 1561, 1562, 1563, 1564 may include a first side part 1561, a second side part 1562, a third side part 1563, and a fourth side part 1564. The first side part 1561 may form the upper side of the cable hole 156 of the PCB plate 150. The second side part 1562 may form the right side of the cable hole 156 of the PCB plate 150. The third side part 1563 may form the left side of the cable hole 156 of the PCB plate 150. The fourth side part 1564 may form the lower side of the cable hole 156 of the PCB plate 150.

The first side part 1561 may include a first rear part 1561a and a first front part 1561b. The first rear part 1561a may be connected to the plate 151 (see FIG. 17) of the PCB plate 150. The first front part 1561b may be formed by folding or curling the first rear part 1561a. The first front part 1561b may face the front surface of the first rear part 1561a.

The second side part 1562 may include a second rear part 1562a and a second front part 1562b. The second rear part 1562a may be connected to the plate 151 of the PCB plate 150. The second front part 1562b may be formed by folding or curling the second rear part 1562a. The second front part 1562b may face the front surface of the second rear part 1562a.

The third side part 1563 may include a third rear part 1563a and a third front part 1563b. The third rear part 1563a may be connected to the plate 151 of the PCB plate 150. The third front part 1563b may be formed by folding or curling the third rear part 1563a. The third front part 1563b may face the front surface of the third rear part 1563a.

The fourth side part 1564 may be connected to the plate 151 of the PCB plate 150.

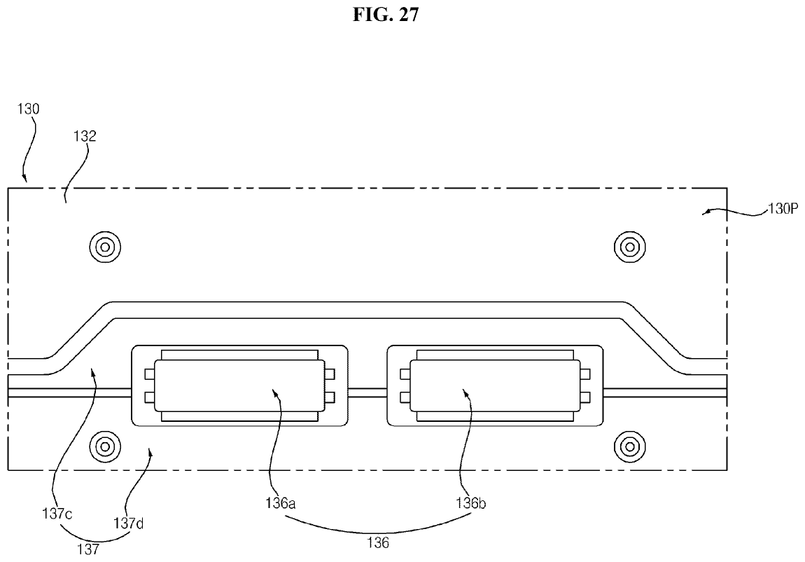

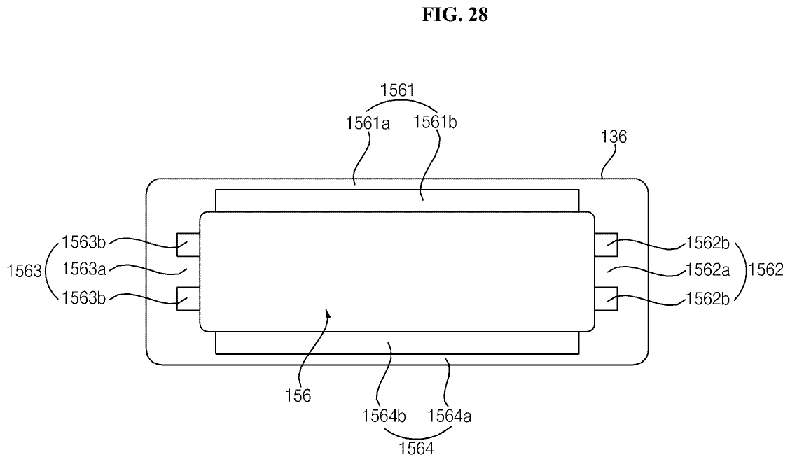

Referring to FIGS. 27 and 28, the PCB plate 150 may include a hole side part 1561, 1562, 1563, 1564. The hole side part 1561, 1562, 1563, 1564 may form the perimeter of the cable hole 156 of the PCB plate 150. The size of the cable hole 156 of the PCB plate 150 may be smaller than the size of the cable hole 136 of the material complexed panel 130.

The hole side part 1561, 1562, 1563, 1564 may include a first side part 1561, a second side part 1562, a third side part 1563, and a fourth side part 1564. The first side part 1561 may form the upper side of the cable hole 156 of the PCB plate 150. The second side part 1562 may form the right side of the cable hole 156 of the PCB plate 150. The third side part 1563 may form the left side of the cable hole 156 of the PCB plate 150. The fourth side part 1564 may form the lower side of the cable hole 156 of the PCB plate 150.

The first side part 1561 may include a first rear part 1561a and a first front part 1561b. The first rear part 1561a may be connected to the plate 151 (see FIG. 17) of the PCB plate 150. The first front part 1561b may be formed by folding or curling the first rear part 1561a. The first front part 1561b may face the front surface of the first rear part 1561a.

The second side part 1562 may include a second rear part 1562a and a second front part 1562b. The second rear part 1562a may be connected to the plate 151 of the PCB plate 150. The second front part 1562b may be formed by folding or curling the second rear part 1562a. There may be a plurality of second front parts 1562b. The second front part 1562b may face the front surface of the second rear part 1562a.

The third side part 1563 may include a third rear part 1563a and a third front part 1563b. The third rear part 1563a may be connected to the plate 151 of the PCB plate 150. The third front part 1563b may be formed by folding or curling the third rear part 1563a. There may be a plurality of third front parts 1563b. The third front part 1563b may face the front surface of the third rear part 1563a.

The fourth side part 1564 may include a fourth rear part 1564a and a fourth front part 1564b. The fourth rear part 1564a may be connected to the plate 151 of the PCB plate 150. The fourth front part 1564b may be formed by folding or curling the fourth rear part 1564a. The fourth front part 1564b may face the front surface of the fourth rear part 1564a.

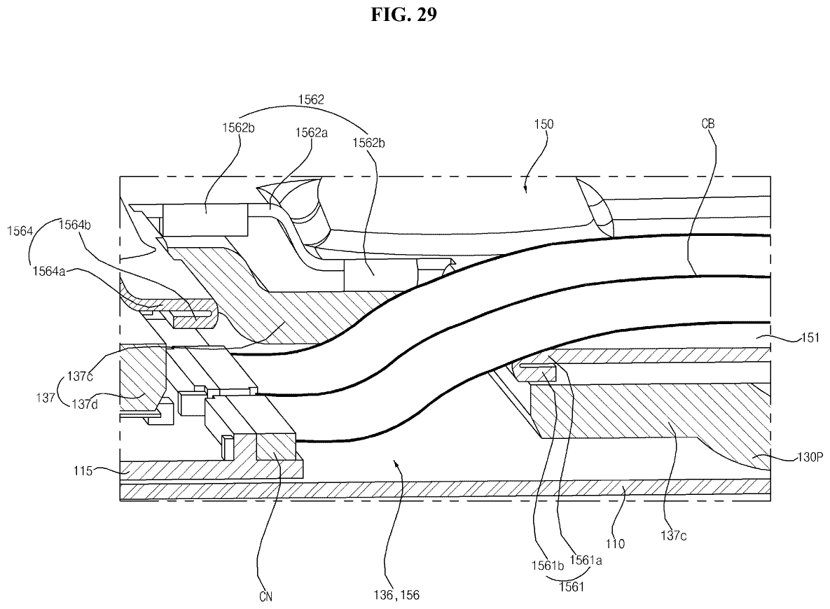

Referring to FIG. 29 together with FIG. 15, the display panel 110 may be coupled to the front surface of the material complexed panel 130. The source signal substrate 115 may be electrically connected to the display panel 110. The source signal substrate 115 may be connected to the display panel 110 by the flexible cable 113. The source signal substrate 115 may be located between the rear surface of the display panel 110 and the receiving portion 137 of the material complexed panel 130. The source signal substrate 115 may be located in a space formed between the receiving portion 137 of the material complexed panel 130 and the rear surface of the display panel 110.

The source signal substrate 115 may be adjacent to or overlapped with the cable hole 136 of the material complexed panel 130. The cable hole 156 of the PCB plate 150 may be aligned with the cable hole 136 of the material complexed panel 130. A flexible flat cable CB may be connected to the source signal substrate 115. The flexible flat cable CB may be connected to the source signal substrate 115 by the connector CN.

The flexible flat cable CB may pass through the cable hole 136 of the material complexed panel 130 and the cable hole 156 of the PCB plate 150 and extend to the rear of the PCB plate 150. The fracture surface of the front skin 132 (see FIG. 2) and/or the rear skin 133 through which the cable hole 136 is penetrated may be formed roughly, and the cable CB passing through the cable hole 136 may be damaged.

The flexible flat cable CB may be in contact with the hole side part 1561, 1562, 1564 of the PCB plate 150 or may be supported by the hole side part 1561, 1562, 1564. Accordingly, the flexible flat cable CB may be prevented from being damaged.

Referring to FIGS. 1 to 29, the display device includes: a display panel 110; a material complexed plate 130 located at a rear of the display panel 110; and a side frame 140 which is located between the display panel 110 and the material complexed plate 130, fixed to the material complexed plate 130, and to which the display panel 110 is coupled, in which the material complexed plate 130 includes: a front skin 132 forming a front surface; a rear skin 133 which forms a rear surface, and faces the front skin 132; a core 131 which is located between the front skin 132 and the rear skin 133, and contains fibers; a receiving portion 137 in which the front skin 132 and the core 131 is compressed to form a step difference that lowers the front skin 132; and a first cable hole 136 which is located adjacent to the receiving portion 137, and penetrates the front skin 132 and the rear skin 133.

The display device further includes a PCB plate 150 which is located at a rear of the material complexed plate 130, coupled to a rear surface of the material complexed plate 130, and covers the first cable hole 136, in which the PCB plate 150 includes a second cable hole 156 facing the first cable hole 136.

A size of the second cable hole 156 is smaller than a size of the first cable hole 136.

The PCB plate 150 includes a hole side part forming a perimeter of the second cable hole 156, in which the hole side part includes: a first side part 1561 forming an upper side; a second side part 1564 forming a lower side facing the upper side; a third side part 1563 connecting the first side part 1561 and the second side part 1564; and a fourth side part 1562 which faces the third side part 1563, and connects the first side part 1561 and the second side part 1564, in which at least one of the first side part 1561, the second side part 1564, the third side part 1563, and the fourth side part 1562 is exposed to a front surface of the material complexed plate 130 by the first cable hole 136.

The PCB plate 150 includes a hole side part 1561, 1562, 1563, 1564 forming a perimeter of the second cable hole 156, in which the hole side part 1561, 1562, 1563, 1564 includes: a rear part 1561a, 1562a, 1563a, 1564a connected to the PCB plate 150; and a front part 1561b, 1562b, 1563b, 1564b that extends while being folded or bent from the rear part 1561a, 1562a, 1563a, 1564a.

The display device further includes: a source signal substrate 115 located in the receiving portion 137 at between the display panel 110 and the material complexed plate 130; and a flexible flat cable CB, FFC which is connected to the source signal substrate 115, and extends from a front of the material complexed plate 130 to a rear of the material complexed plate 130 through the first cable hole 136.

The display device further includes a flexible cable 113 connecting the source signal substrate 115 and the display panel 110, in which the flexible cable 113 is located between the display panel 110 and the material complexed plate 130.

The display device further includes a PCB plate 150 which is located at a rear of the material complexed plate 130, coupled to a rear surface of the material complexed plate 130, and covers the first cable hole 136,
in which the PCB plate 150 includes a second cable hole 156 facing the first cable hole 136, in which the flexible flat cable CB, FFC extends to a rear of the PCB plate 150 through the first cable hole 136 and the second cable hole 156.

The PCB plate 150 includes a hole side part 1561, 1562, 1563, 1564 forming a perimeter of the second cable hole 156, in which the hole side part 1561, 1562, 1563, 1564 includes: a rear part 1561a, 1562a, 1563a, 1564a connected to the PCB plate 150; and a front part 1561b, 1562b, 1563b, 1564b that extends while being folded or bent from the rear part 1561a, 1562a, 1563a, 1564a.

A size of the second cable hole 156 is smaller than a size of the first cable hole 136.

The front surface of the second cable hole 156 is exposed to the front of the material complexed plate 130 through the first cable hole 136.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a material complexed plate located at a rear of the display panel; and
a side frame which is located between the display panel and the material complexed plate, fixed to the material complexed plate, and to which the display panel is coupled,
wherein the material complexed plate comprises:
a front skin forming a front surface;
a rear skin which forms a rear surface, and faces the front skin;
a core which is located between the front skin and the rear skin, and contains fibers;
a receiving portion in which the front skin and the core is compressed to form a step difference that lowers the front skin; and
a first cable hole which is located adjacent to the receiving portion, and penetrates the front skin and the rear skin.

2. The display device of claim 1, further comprising a PCB plate which is located at a rear of the material complexed plate, coupled to a rear surface of the material complexed plate, and covers the first cable hole,
wherein the PCB plate comprises a second cable hole facing the first cable hole.

3. The display device of claim 2, wherein a size of the second cable hole is smaller than a size of the first cable hole.

4. The display device of claim 2, wherein the PCB plate comprises a hole side part forming a perimeter of the second cable hole,
wherein the hole side part comprises:
a first side part forming an upper side;
a second side part forming a lower side facing the upper side;
a third side part connecting the first side part and the second side part; and
a fourth side part which faces the third side part, and connects the first side part and the second side part,
wherein at least one of the first side part, the second side part, the third side part, and the fourth side part is exposed to a front surface of the material complexed plate by the first cable hole.

5. The display device of claim 2, wherein the PCB plate comprises a hole side part forming a perimeter of the second cable hole,
wherein the hole side part comprises:
a rear part connected to the PCB plate; and
a front part that extends while being folded or bent from the rear part.

6. The display device of claim 1, further comprising:
a source signal substrate located in the receiving portion at between the display panel and the material complexed plate; and
a flexible flat cable which is connected to the source signal substrate, and extends from a front of the material complexed plate to a rear of the material complexed plate through the first cable hole.

7. The display device of claim 6, further comprising a flexible cable connecting the source signal substrate and the display panel,
wherein the flexible cable is located between the display panel and the material complexed plate.

8. The display device of claim 6, further comprising a PCB plate which is located at a rear of the material complexed plate, coupled to a rear surface of the material complexed plate, and covers the first cable hole,
wherein the PCB plate comprises a second cable hole facing the first cable hole,
wherein the flexible flat cable extends to a rear of the PCB plate through the first cable hole and the second cable hole.

9. The display device of claim 8, wherein the PCB plate comprises a hole side part forming a perimeter of the second cable hole,
wherein the hole side part comprises:
a rear part connected to the PCB plate; and
a front part that extends while being folded or bent from the rear part.

10. The display device of claim 9, wherein a size of the second cable hole is smaller than a size of the first cable hole.

11. The display device of claim 9, wherein the hole side part is exposed to the front of the material complexed plate through the first cable hole.
